(19) United States
(12) Patent Application Publication
(10) Pub. No.: US 2023/0215723 A1
(43) Pub. Date: Jul. 6, 2023

(54) METHODS OF MANUFACTURING INTEGRATED CIRCUIT DEVICES USING CARBONYL COMPOUNDS

(71) Applicant: Samsung Electronics Co., Ltd., Suwon-si (KR)

(72) Inventors: EUNHYEA KO, Suwon-si (KR); Hoon Han, Anyang-si (KR); Soyoung Lee, Hwaseong-si (KR); Thanh Cuong Nguyen, Hwaseong-si (KR); Hiroyuki Uchiuzou, Tokyo (JP); Kiyoshi Murata, Tokyo (JP); Tomoharu Yoshino, Tokyo (JP); Daekeon Kim, Hwaseong-si (KR); Younjoung Cho, Hwaseong-si (KR); Jiyu Choi, Suwon-si (KR); Byungkeun Hwang, Seongnam-si (KR)

(73) Assignee: ADEKA CORPORATION, Tokyo (JP)

(21) Appl. No.: 18/147,733

(22) Filed: Dec. 29, 2022

(30) Foreign Application Priority Data
Dec. 31, 2021 (KR) 10-2021-0194552
Nov. 15, 2022 (KR) 10-2022-0152841

(51) Int. Cl. H01L 21/02; C23C 16/455; C23C 2/02; H01L 21/311

(52) U.S. Cl. CPC H01L 21/0217; H01L 21/02323; H01L 21/0226; C23C 16/45525; C23C 2/026; H01L 21/31116

(57) ABSTRACT

To manufacture an integrated circuit (IC) device, a structure in which a first material film including silicon atoms and nitrogen atoms and a second material film devoid of nitrogen atoms is formed on a substrate. A carbonyl compound having a functional group without an α-hydrogen is applied to the structure, and thus, an inhibitor is selectively formed only on an exposed surface of the first material film from among the first material film and the second material film.

### CROSS-REFERENCE TO RELATED APPLICATION

This application is based on and claims priority under 35 U.S.C. §119 to Korean Patent Application No. 10-2021-0194552, filed on Dec. 31, 2021, in the Korean Intellectual Property Office, and Korean Patent Application No. 10-2022-0152841, filed on Nov. 15, 2022, in the Korean Intellectual Property Office, the disclosures of which are incorporated by reference herein in their entirety.

### BACKGROUND

The inventive concept relates to methods of manufacturing integrated circuit (IC) devices, and more particularly, to methods of manufacturing IC devices using carbonyl compounds.

In recent years, due to the development of electronic technology, the downscaling of semiconductor devices has rapidly progressed, and thus, patterns included in electronic devices have been miniaturized. Accordingly, in processes for manufacturing IC devices, it is necessary to develop techniques for selectively protecting films including specific materials on a surface in which a plurality of films of different materials are exposed.

### SUMMARY

The inventive concept provides methods of manufacturing an integrated circuit (IC) device, which may selectively protect only a film including a nitride-based material including silicon atoms and nitrogen atoms on a surface at which a plurality of films including different materials are exposed during a process of manufacturing the IC device, thereby improving the manufacturing efficiency and reliability of the IC device.

According to an aspect of the inventive concept, there is provided a method of manufacturing an IC device. The method includes forming a structure on a substrate including a first material film and a second material film. The first material film includes silicon atoms and nitrogen atoms and the second material film is devoid of nitrogen atoms, with the first material film and second material film having exposed surfaces in the structure. A carbonyl compound having (i.e., including) a functional group without an α-hydrogen is applied to the structure, and thus, an inhibitor liner is selectively formed only on the exposed surface of the first material film from among the first material film and the second material film, and no inhibitor liner is formed on the exposed surface of the second material film.

According to another aspect of the inventive concept, there is provided a method of manufacturing an IC device. The method includes forming a structure on a substrate. The structure includes a first material film including silicon atoms and nitrogen atoms and a second material film that is devoid of nitrogen atoms. The structure is preprocessed to expose a first surface having an amine group (—NH₂) in the first material film and expose a second surface having a hydroxy group (—OH) in the second material film. A carbonyl compound having (i.e., including) a functional group without an α-hydrogen is applied to the first surface and the second surface, and an inhibitor liner is selectively formed only on the first surface and not on the second surface.

According to another aspect of the inventive concept, there is provided a method of manufacturing an IC device. The method includes forming a structure on a substrate. A nitride film including silicon atoms and nitrogen atoms and an oxide film that is devoid of nitrogen atoms are formed and each film includes an exposed surface in the structure. A carbonyl compound having (i.e., including) a functional group without an α-hydrogen is applied to the nitride film and the oxide film, and thus, an inhibitor liner is selectively formed only on the nitride film from among the nitride film and the oxide film. The carbonyl compound includes an aldehyde compound, which is represented by General Formula 1A, General Formula 1B, or General Formula 1C:

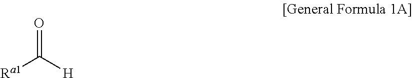

wherein R^{a1} is a substituted or unsubstituted C6 to C20 aryl group, a substituted or unsubstituted C2 to C20 heteroaryl group, a substituted or unsubstituted C7 to C20 alkylaryl group, or a combination thereof.

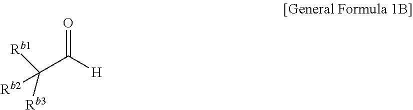

wherein each of R^{b1}, R^{b2}, and R^{b3} is a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

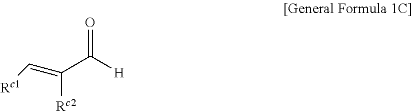

wherein each of R^{c1} and R^{c2} is a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

### BRIEF DESCRIPTION OF THE DRAWINGS

Embodiments of the inventive concept will be more clearly understood from the following detailed description taken in conjunction with the accompanying drawings in which:

FIG. 1 is a flowchart of a method of manufacturing an integrated circuit (IC) device, according to embodiments of the invention;

FIG. 2 is a flowchart of a method of manufacturing an IC device according to embodiments of the invention;

FIGS. 3A to 3C are cross-sectional views of a process sequence for explaining in detail a method of manufacturing an IC device according to embodiments of the invention;

FIGS. 4A to 4C are cross-sectional views of a process sequence for explaining in detail a method of manufacturing an IC device according to embodiments of the invention;

FIGS. 5A to 5C are cross-sectional views of a process sequence for explaining in detail a method of manufacturing an IC device according to embodiments of the invention; and

FIG. 6 is a potential energy diagram for explaining a reaction between an inhibitor material to be evaluated and a surface of a film to be evaluated.

### DETAILED DESCRIPTION OF THE EMBODIMENTS

Hereinafter, embodiments of the inventive concept will be described in detail with reference to the accompanying drawings. Like reference numerals in the accompanying drawings refer to like elements throughout, and duplicate descriptions thereof are omitted.

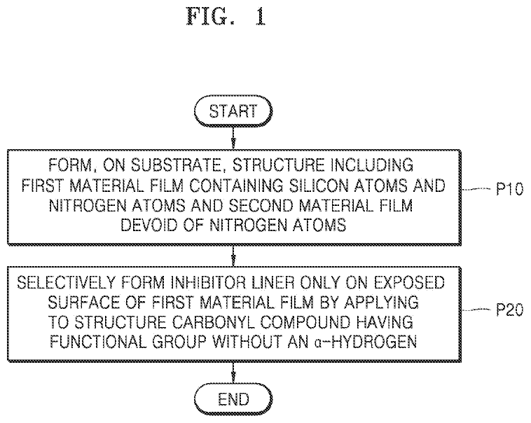

FIG. 1 is a flowchart of a method of manufacturing an integrated circuit (IC) device according to embodiments of the invention.

Referring to FIG. 1, in process P10, a structure including a first material film containing silicon atoms and nitrogen atoms and a second material film that is devoid of nitrogen atoms may be formed on a substrate. The term “devoid of nitrogen atoms,” as used herein, means that the material is not formed from a compound or substance having nitrogen as a component element, and so a material that is devoid of nitrogen atoms may include trace amounts of nitrogen atoms (e.g., less than 1%, 0.5%, or 0.1%).

In some embodiments, the substrate may include a semiconductor substrate. For example, the substrate may include a semiconductor substrate and a lower structure on the semiconductor substrate. In some embodiments, the lower structure may include various conductive regions (e.g., a wiring layer, a contact plug, and a transistor) and insulating patterns configured to insulate the conductive regions from each other.

In some embodiments, the first material film may include silicon nitride (SiN), silicon oxynitride (SiON), silicon oxycarbonitride (SiCON), silicon boron nitride (SiBN), silicon carbonitride (SiCN), or a combination thereof. As used herein, each of the terms “SiN,” “SiON,” “SiCON,” “SiBN,” and “SiCN” refers to a material including the stated elements therein without referring to a chemical formula representing a particular stoichiometric relationship.

In some embodiments, the second material film may include a silicon oxide film or a metal-containing film. In example embodiments, the silicon oxide film may include Sift, borosilicate glass (BSG), phosphosilicate glass (PSG), borophosphosilicate glass (BPSG), undoped silicate glass (USG), tetraethylorthosilicate glass (TEOS), or a combination thereof, without being limited thereto. In example embodiments, the metal-containing film may include tungsten (W), cobalt (Co), ruthenium (Ru), or a combination thereof, without being limited thereto.

After the structure is formed in process P10, the first material film may have a first surface in which an amine group (e.g., —NH₂) is exposed, and the second material film may have a second surface in which a hydroxy group (—OH) is exposed.

In process P20 of FIG. 1, a carbonyl compound having a functional group without an α-hydrogen (i.e., there is no hydrogen atom attached to a carbon atom that is attached to the carbonyl moiety) may be applied to the structure formed in process P10, and thus, an inhibitor liner may selectively be formed only on the first surface of the first material film from among the first material and the second material film. That is, the inhibitor liner may form on the first surface of the first material film but may not form, or may not substantially form, on the second surface of the second material film. The inhibitor liner may include the functional group included in the carbonyl compound or a derivative thereof.

In example embodiments, the carbonyl compound may include an aldehyde compound represented by the following General Formula 1:

R¹—C(═O)—H [General Formula 1]

wherein R¹ is a substituted or unsubstituted hydrocarbon group that does not have an α-hydrogen. In some embodiments, R¹ may be a substituted or unsubstituted C1 to C30 branched alkyl group, a substituted or unsubstituted C3 to C30 branched alkenyl group, a substituted or unsubstituted C2 to C30 alkynyl group, a substituted or unsubstituted C1 to C30 branched alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

In example embodiments, in General Formula 1, R¹ may include a hydrocarbyl group, which is substituted with at least one heteroatom-containing functional group such as an oxygen atom, a nitrogen atom, a halogen, cyano, silyl, ether, carbonyl, ester, nitro, amino, or a combination thereof. The halogen may be fluorine (F), chlorine (Cl), bromine (Br), or iodine (I).

In example embodiments, in General Formula 1, R¹ may include at least one electron-withdrawing group. As used herein, the term “electron-withdrawing group,” which is a known term in the art, refers to a group that withdraws electrons more strongly than a hydrogen atom does at the same site. The at least one electron-withdrawing group may include a C1 to C10 alkyl group substituted with one or more fluorine atom(s), a C1 to C10 alkoxy group substituted with one or more fluorine atom(s), a C1 to C10 cycloalkyl group substituted with one or more fluorine atom(s), a cyano group (—CN), a nitrile group, a nitro group (—NO₂), a carboxyl group, or a combination thereof. For example, the at least one electron-withdrawing group may include a trifluoromethyl group, a trifluoroethyl group, a pentafluoroethyl group, a hexafluoroisopropanol group, and/or a heptafluorobutyl group, without being limited thereto.

In example embodiments, when the carbonyl compound includes the aldehyde compound that is represented by General Formula 1, the carbonyl compound may be represented by the following General Formula 1A, General Formula 1B, or General Formula 1C:

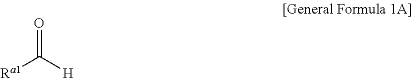

wherein R^{a1} is a substituted or unsubstituted C6 to C20 aryl group, a substituted or unsubstituted C2 to C20 heteroaryl group, a substituted or unsubstituted C7 to C20 alkylaryl group, or a combination thereof.

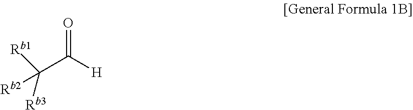

wherein each of R^{b1}, R^{b2}, and R^{b3} is independently a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

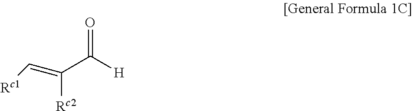

wherein each of R^{c1} and R^{c2} is independently a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

In example embodiments, in General Formula 1, R¹ may be a t-butyl group, a t-pentyl group(1,1-dimethylpropyl group), a t-hexyl group, a t-heptyl group, a 1,1,3,3-tetramethylbutyl group, a 1-ethyl-1-methyl-hexyl group, a 1-methyl-1-hydroxyethyl group, a 1-methylethenyl group, a 1-methyl-1-hexenyl group, a 1,1,5-trimethyl-5-hexenyl group, a 1-ethenyl-1,5-dimethyl-4-hexen-1-yl group, a or a 1-isobutyl-1-methyl-2-propynyl group, without being limited thereto.

In other example embodiments, in General Formula 1, R¹ may be an aromatic ring, a heteroaromatic ring, or a combination thereof. As an example, the aromatic ring may include a single aromatic ring, such as benzene; a heteroaryl group, such as pyridine, pyrimidine, and thiophene; and/or a condensed aryl group, such as quinolone, isoquinoline, naphthalene, anthracene, and phenanthrene. In some embodiments, the heteroaryl group and the condensed aryl group may include at least one heteroatom selected from an oxygen (O) atom and a nitrogen (N) atom.

In example embodiments, the carbonyl compound may be a substituted or unsubstituted benzaldehyde compound. For example, the carbonyl compound may include an aldehyde compound that is represented by the following General Formula 1D:

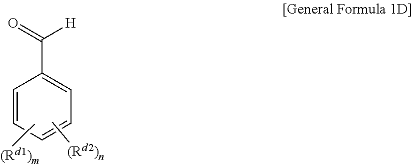

wherein R^{d1} is a methyl group or a trifluoromethyl group, R^{d2} is a C1 to C4 alkyl group, a C1 to C4 alkoxy group, a halogen, a hydroxy group, a nitro group, an amino group, a C1 to C4 monoalkylamino group, or C1 to C4 dialkylamino group, or a combination thereof and each of m and n is an integer of 0 to 3, and 0≤(m+n)≤5.

In some embodiments, the carbonyl compound may be 4-(trifluoromethyl)benzaldehyde, 3 -(trifluoromethyl)benzaldehyde, 3,5-bis(trifluoromethyl)benzaldehyde, phenylpropargyl aldehyde, 2-octynal, or a combination thereof, without being limited thereto.

In other example embodiments, the carbonyl compound may include a substituted or unsubstituted ketone compound. For instance, the carbonyl compound may include a ketone compound that is represented by the following General Formula 2:

R²¹—C(═O)—R²² [General Formula 2]

wherein R²¹ is a hydrocarbon group without an α-hydrogen, and is a substituted or unsubstituted C1 to C30 branched alkyl group, a substituted or unsubstituted C3 to C30 branched alkenyl group, a substituted or unsubstituted C2 to C30 alkynyl group, a substituted or unsubstituted C1 to C30 branched alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof, and R²² is a substituted or unsubstituted C1 to C6 alkyl group, a substituted or unsubstituted C2 to C6 alkenyl group, a substituted or unsubstituted C2 to C6 alkynyl group, or a combination thereof.

In example embodiments, in General Formula 2, each of R²¹ and R²² may include a hydrocarbyl group substituted with at least one heteroatom-containing functional group such as an oxygen atom, a nitrogen atom, a halogen, cyano, silyl, ether, carbonyl, ester, nitro, amino, or a combination thereof. The halogen may be F, Cl, Br, or I.

In example embodiments, in General Formula 2, R²¹ may have the same example structure as R¹ of General Formula 1 described above. In example embodiments, in General Formula 2, R²² may be a methyl group or a trifluoromethyl group.

For example, the carbonyl compound may include a ketone compound that is represented by the following General Formula 2A:

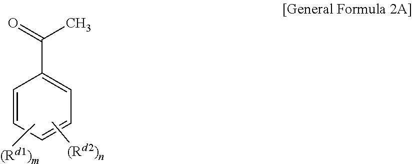

wherein R^{d1} is a methyl group or a trifluoromethyl group, R^{d2} is a C1 to C4 alkyl group, a C1 to C4 alkoxy group, a halogen, a hydroxy group, a nitro group, an amino group, a C1 to C4 monoalkylamino group, a C1 to C4 dialkylamino group, or a combination thereof, and each of m and n is an integer of 0 to 3, and 0≤(m+n)≤5.

For example, the carbonyl compound may be 3,5-bis(trifluoromethyl)acetophenone, without being limited thereto.

During the formation of the inhibitor liner according to process P20 of FIG. 1, hydroxyl groups in the exposed surface of the second material film may not react with the carbonyl compound.

In example embodiments, the process of forming the inhibitor liner according to the process P20 of FIG. 1 may be performed in a wet manner. For example, the structure formed in process P10 of FIG. 1 may be dipped in an inhibitor solution including the carbonyl compound having the functional group with an α-hydrogen. For example, the inhibitor solution may include the carbonyl compound and an organic solvent or may solely include the carbonyl compound.

In other example embodiments, the process of forming the inhibitor liner according to process P20 of FIG. 1 may be performed in a dry manner. For example, the inhibitor liner may be selectively formed on an exposed surface of the first material film by using an atomic layer deposition (ALD) process using, as a source material, the carbonyl compound having the functional group without an α-hydrogen.

In example embodiments, after the inhibitor liner is formed according to the process P20 of FIG. 1, only the second material film may be selectively processed as the inhibitor liner acts as a blocking layer. For example, the second material film may be etched using the inhibitor liner on the first material film as an etch mask.

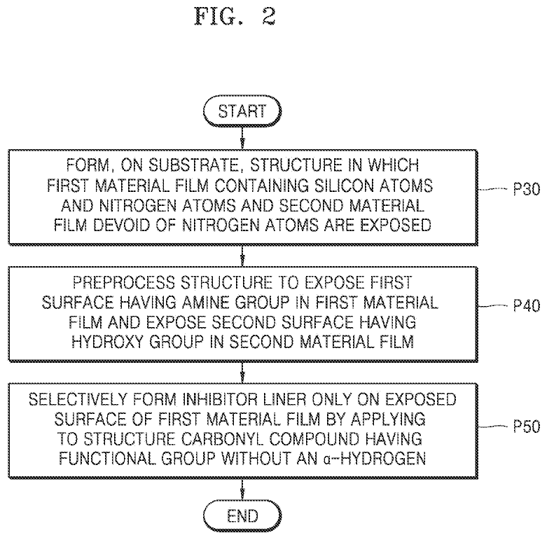

FIG. 2 is a flowchart of a method of manufacturing an IC device, according to embodiments of the invention.

Referring to FIG. 2, in process P30, a structure including a first material film containing silicon atoms and nitrogen atoms and a second material film that is devoid of nitrogen atoms may be formed on a substrate. The substrate, the first material film, and the second material film may be understood in further detail with reference to the description of process P10 of FIG. 1.

In process P40 of FIG. 2, the structure may be preprocessed to expose a first surface having an amine group (e.g., —NH₂) in the first material film and expose a second surface having a hydroxy group (—OH) in the second material film.

In some embodiments, preprocessing the structure may include dry cleaning, wet cleaning, dry etching, or wet etching a portion of the structure formed in process P30 of FIG. 2.

In example embodiments, the dry cleaning process may include a plasma cleaning process using a reactive gas including NH₃, NF₃, O₂, or a combination thereof. In example embodiments, the wet cleaning process may include an ultrasonic cleaning process using an organic solvent, a lift-off cleaning process, or a cleaning process for dissolving a material to be removed. In the ultrasonic cleaning process, dichloromethane, acetone, or methanol, for example, may be used as the organic solvent. The lift-off cleaning process may be performed, for example, using an SC-1 cleaning solution including NH₄OH, H₂O₂, and H₂O, or a diluted hydrofluoric acid (DHF) cleaning solution including HF and H₂O. The cleaning process for dissolving the material to be removed may be performed, for example, using a sulfuric acid (H₂SO₄) and hydrogen peroxide (H₂O₂) mixture (SPM) cleaning solution including H₂SO₄ and H₂O₂, an SC-2 cleaning solution including HCl, H₂O₂, and H₂O, a DHF cleaning solution including HF and H₂O, or a buffered oxide etchant (BOE) cleaning solution including NH₄F, H₂O, and a surfactant. However, specific methods of performing the dry and wet cleaning processes are not limited to the examples described above.

In process P50 of FIG. 2, the same method as that described in process P20 of FIG. 1 may be performed on the resultant structure that is preprocessed according to process P40 of FIG. 2. Thus, a carbonyl compound having a functional group without an α-hydrogen may be applied to the first surface of the first material film and the second surface of the second material film. As a result, an inhibitor liner may selectively be formed only on the first surface of the first material film, and no inhibitor liner is formed on the second surface of the second material film. The inhibitor liner may include the functional group included in the carbonyl compound or a derivative thereof.

The present inventors confirmed via simulations and experiments that, among carbonyl compounds, an inhibitor liner could be selectively formed on a surface of a silicon nitride film by using a carbonyl compound having a functional group without an α-hydrogen. In addition, it was confirmed that selective deposition characteristics of the carbonyl compound on the surface of the silicon nitride film were maximized when the functional group of the carbonyl compound without an α-hydrogen included an electron-withdrawing group.

For example, an aldehyde compound, which is a kind of the carbonyl compound, may cause the same reaction as in Reaction scheme 1A or Reaction scheme 1B on the surface of the silicon nitride film. Here, when the aldehyde compound has a functional group R which lacks an α-hydrogen, a reaction according to Reaction scheme 1A may occur. When the aldehyde compound has a functional group R in which an α-hydrogen is present, a reaction according to Reaction scheme 1B may occur.

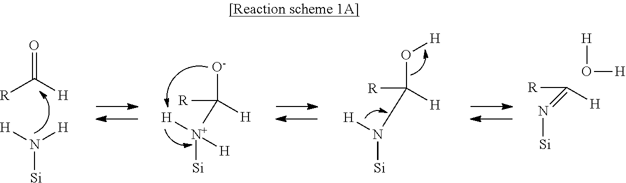

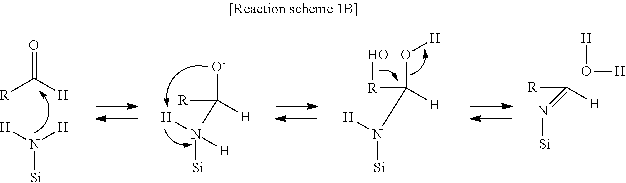

Furthermore, the aldehyde compound may be considered to cause the reaction according to Reaction scheme 2A or the reaction according to Reaction scheme 2B on a surface of a silicon oxide film.

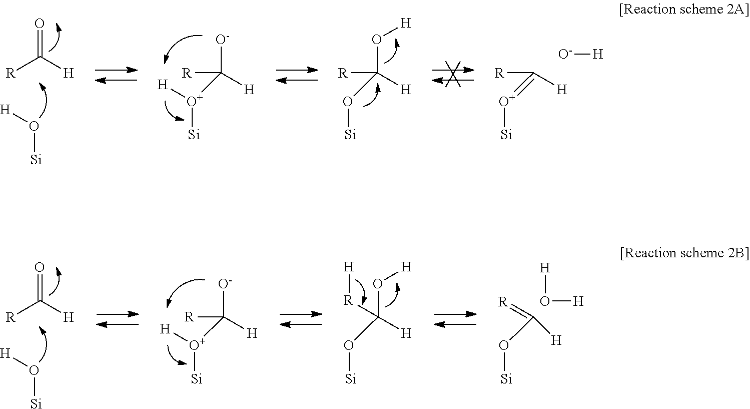

However, because the activation energy is excessively high, it may be difficult to cause a reaction of generation of an oxonium ion, which is a positively charged oxygen ion having three bonds, as in the reaction according to Reaction scheme 2A. However, when the aldehyde compound has a functional group R in which the α-hydrogen is present, a reaction may proceed as in Reaction scheme 2B. Activation energy in the reaction according to Reaction scheme 2B may not be much different from that in the reaction according to Reaction scheme 1B, which is a reaction on the silicon nitride film.

Therefore, it may be necessary to block a reaction path as in Reaction scheme 2B in order that the aldehyde compound selectively deposits on the silicon nitride film over the silicon oxide film. That is, when the aldehyde compound has a functional group R without an α-hydrogen, the reaction path as in Reaction scheme 2B may be blocked and no inhibitor liner, or substantially no inhibitor liner, is formed on the silicon oxide.

In particular, when the functional group R without an α-hydrogen includes an electron-withdrawing group, electrons may be removed from the α-carbon site in the functional group R and the reaction according to Reaction scheme 1A may be more highly likely to occur.

Therefore, in a method of manufacturing the IC device according to some embodiments, when a carbonyl compound (e.g., an aldehyde compound) having a functional group without an α-hydrogen is applied to a surface of a silicon nitride film having an amine group, a dehydration reaction may occur by a reaction of an aldehyde group of the aldehyde compound with the amine group. As a result, an imine functional group (—HN═C-) may be formed, and thus, an inhibitor liner having the functional group R or a derivative thereof may be selectively formed on the silicon nitride film. When the carbonyl compound includes an aldehyde compound represented by General Formula 1, the functional group R may have the same structure as R¹ defined in General Formula 1.

Although Reaction schemes 1A, 1B, 2A, and 2B pertain to examples in which the carbonyl compound includes the aldehyde compound, even when the carbonyl compound includes a ketone compound, results similar to those described with reference to Reaction schemes 1A, 1B, 2A, and 2B may be obtained. That is, by applying a ketone compound having a functional group (e.g., R²¹ of General Formula 2) without an α-hydrogen to a surface of a silicon nitride film having an amine group, an inhibitor liner including the functional group (e.g., R²¹ of General Formula 2) may be selectively formed on the silicon nitride film.

In a method of manufacturing the IC device according to some embodiments, when the inhibitor liner is selectively formed on the silicon nitride film by using the carbonyl compound having a functional group without an α-hydrogen, the carbonyl compound that may be used is not limited to example materials described herein, and any materials capable of selectively reacting with an amine group may fall within the scope of the inventive concept. Furthermore, when the inhibitor liner is selectively formed on the silicon nitride film, embodiments are not limited to the formation of an imine functional group between the functional group in which no α-hydrogen exists and the surface of the silicon nitride film as in Reaction scheme 1A, and various bonding structures may be formed between the functional group and the surface of the silicon nitride film.

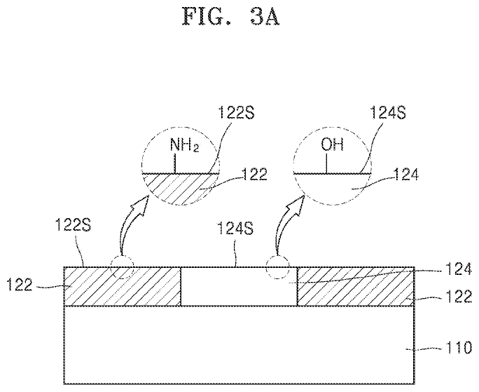

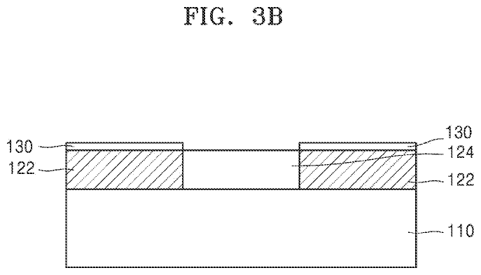

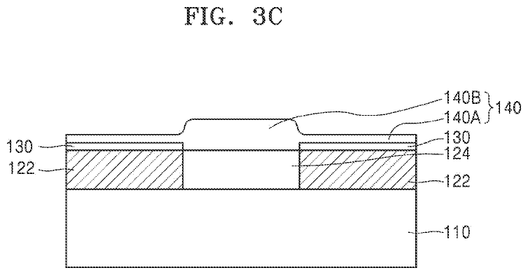

FIGS. 3A to 3C are cross-sectional views of a process sequence for explaining in detail a method of manufacturing an IC device according to some embodiments of the invention.

Referring to FIG. 3A, a structure in which a first material film 122 and a second material film 124 are exposed may be formed on a substrate 110. The substrate 110, the first material film 122, and the second material film 124 may be understood in further detail with reference to the description of the substrate, the first material film, and the second material in process P10 of FIG. 1. For example, the first material film 122 may include a silicon nitride film, and the second material film 124 may include a silicon oxide film. The first material film 122 may have a first surface 122S at which an amine group (—NH₂) is exposed, and the second material film 124 may have a second surface 124S at which a hydroxy group (—OH) is exposed.

In example embodiments, the structure shown in FIG. 3A may be obtained as a result of the process described in process P10 of FIG. 1 or the processes described in processes P30 and P40 of FIG. 2.

Referring to FIG. 3B, according to the same method as that described in process P20 of FIG. 1, a carbonyl compound having a functional group without an α-hydrogen may be applied to the resultant structure of FIG. 3A. Thus, an inhibitor liner 130 may selectively be formed only on the first surface 122S of the first material film 122 from among the first surface 122S of the first material film 122 and the second surface 124S of the second material film 124. The inhibitor liner 130 may not be formed, or may not substantially be formed, on the second surface 124S of the second material film 124 due to the selective deposition characteristics of the carbonyl compound.

Examples of the carbonyl compound having a functional group without an α-hydrogen are the same as those described with reference to P10 of FIG. 1. The inhibitor liner 130 may include the functional group included in the carbonyl compound or a derivative thereof.

In example embodiments, the process of forming the inhibitor liner 130 may be performed at a temperature selected in a range of about 100° C. to about 300° C., without being limited thereto.

Referring to FIG. 3C, in the resultant structure of FIG. 3B, an upper film 140 may be formed on the first material film 122 and the second material film 124.

The upper film 140 may include a first portion 140A covering the first material film 122 and a second portion 140B covering the second material film 124. On the first material film 122, the upper film 140 may be formed to have a relatively small thickness due to a deposition inhibitory action of the inhibitor liner 130. Accordingly, a thickness of the first portion 140A of the upper film 140 may be less than a thickness of the second portion 140B thereof. In example embodiments, the thickness of the first portion 140A of the upper film 140 may be about 0.5 times to about 0.8 times the thickness of the second portion 140B thereof, without being limited thereto.

In example embodiments, the upper film 140 may include a metal, a metal oxide, a metal nitride, silicon oxide, silicon nitride, or a combination thereof, without being limited thereto. For example, the upper film 140 may include a hafnium oxide film, a hafnium nitride film, an aluminum oxide film, an aluminum nitride film, a niobium oxide film, a niobium nitride film, or a combination thereof, without being limited thereto.

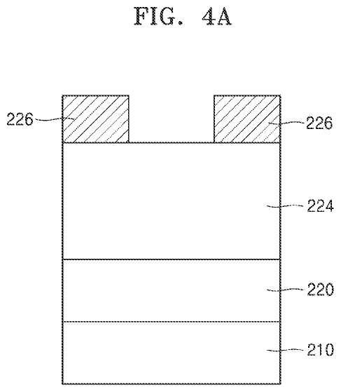

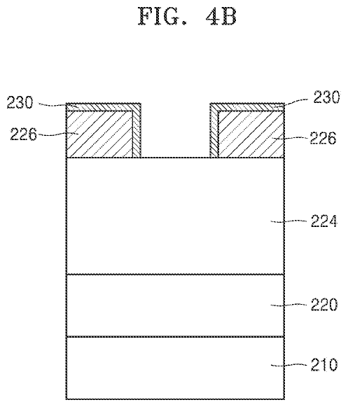

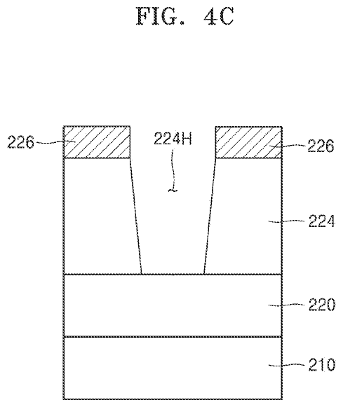

FIGS. 4A to 4C are cross-sectional views of a process sequence for explaining in detail a method of manufacturing an IC device according to some embodiments.

Referring to FIG. 4A, a lower structure 220 may be formed on a substrate 210, and an insulating film 224 may be formed on the lower structure 220.

The substrate 210 may include an element semiconductor, such as silicon (Si) or germanium (Ge), or a compound semiconductor, such as silicon germanium (SiGe), silicon carbide (SiC), gallium arsenide (GaAs), indium arsenide (InAs), or indium phosphide (InP). The substrate 210 may include a conductive region (not shown). In some embodiments, the conductive region may include a doped well, a doped structure, or a conductive layer. In example embodiments, the lower structure 220 may include various conductive regions, for example, a wiring layer, a contact plug, a transistor, and insulating patterns configured to insulate the wiring layer, the contact plug, and the transistor from each other. The insulating film 224 may include a silicon oxide film. For example, the insulating film 224 may include SiO₂, BSG, PSG, BPSG, USG, TEOS, or a combination thereof, without being limited thereto.

A mask pattern 226 may be formed on the insulating film 224. The mask pattern 226 may include a first material film including silicon atoms and nitrogen atoms. For example, the mask pattern 226 may include SiN, SiON, SiCON, SiBN, SiCN, or a combination thereof

A partial surface of the insulating film 224 may be exposed through the mask pattern 226. An amine group (—NH₂) may be exposed at an exposed surface of the mask pattern 226, and a hydroxy group (—OH) may be exposed at an exposed surface of the insulating film 224. The resultant structure described above may be obtained as a result of performing the process described above in process P10 of FIG. 1 or the processes described above in processes P30 and P40 of FIG. 2.

Referring to FIG. 4B, according to the same method as that described in process P20 of FIG. 1, a carbonyl compound having a functional group without an α-hydrogen may be applied to the resultant structure of FIG. 4B, and thus, an inhibitor liner 230 may be formed selectively only on the exposed surface of the mask pattern 226 from among the respective exposed surfaces of the mask pattern 226 and the insulating film 224. The inhibitor liner 230 may not be formed on the exposed surface of the insulating film 224 due to the selective deposition characteristics of the carbonyl compound.

Examples of the carbonyl compound having the functional group without an α-hydrogen are the same as those described with reference to process P10 of FIG. 1. The inhibitor liner 230 may include the functional group included in the carbonyl compound or a derivative thereof.

Referring to FIG. 4C, in the resultant structure of FIG. 4B, the insulating film 224 may be etched using the inhibitor liner 230 and the mask pattern 226 as an etch mask, and thus, a hole 224H may be formed in the insulating film 224.

To etch the insulating film 224, a dry etching process may be performed. During the dry etching process, the inhibitor liner 230 covering the mask pattern 226 may improve an etching resistance of the mask pattern 226 in the dry etching process. For example, during the etching of the insulating film 224, the inhibitor liner 230 may inhibit the consumption of the mask pattern 226 and/or increase an etch selectivity of the insulating film 224 with respect to the mask pattern 226.

During the etching of the insulating film 224 to form the hole 224H in the insulating film 224, at least portions of the inhibitor liner 230 and the mask pattern 226, which are in the resultant structure of FIG. 4B, may be consumed due to an etching atmosphere.

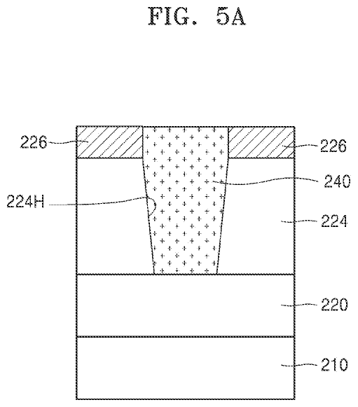

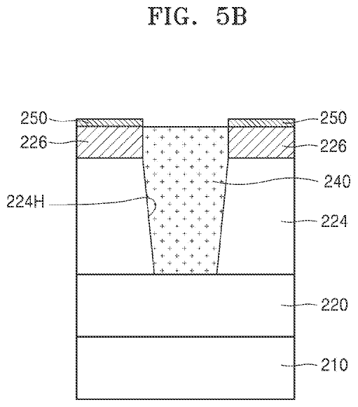

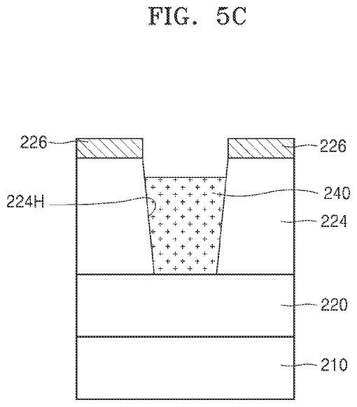

FIGS. 5A to 5C are cross-sectional views of a process sequence for explaining in detail a method of manufacturing an IC device according to some embodiments.

Referring to FIG. 5A, after a structure in which a hole 224H is formed in an insulating film 224 is prepared as shown in FIG. 4C, the structure may be cleaned using a dry cleaning process, a wet cleaning process, or a combination thereof.

A detailed description of the dry cleaning process and the wet cleaning process may be the same as in process P40 of FIG. 2. The resultant structure in which the hole 224H is formed in the insulating film 224 may be cleaned. Thereafter, an amine group (—NH₂) may be exposed at an exposed surface of the mask pattern 226, and a hydroxy group (—OH) may be exposed at a surface of the insulating film 224, which is exposed inside the hole 224H.

In the resultant structure of FIG. 4C, which is cleaned, a conductive structure 240 may be formed to fill the hole 224H of the insulating film 224 and cover a top surface of the mask pattern 226. Afterwards, the obtained resultant structure may be planarized to expose the top surface of the mask pattern 226. The conductive structure 240 may include a metal-containing film. For example, the conductive structure 240 may include W, Co, Ru, or a combination thereof, without being limited thereto.

In some embodiments, the planarization process may be performed using an etchback process or a chemical mechanical polishing (CMP) process. When necessary, a cleaning process may be performed after the planarization process. The cleaning process may be performed using a dry cleaning process, a wet cleaning process, or a combination thereof. A detailed description of the dry cleaning process and the wet cleaning process may be the same as in process P40 of FIG. 2.

Referring to FIG. 5B, according to the same method as that described in process P20 of FIG. 1, a carbonyl compound having a functional group without an α-hydrogen may be applied to the resultant structure of FIG. 5A. Thus, an inhibitor liner 250 may be formed selectively only on the exposed surface of the mask pattern 226 from among the exposed surfaces of the mask pattern 226 and the conductive structure 240. The inhibitor liner 250 may not be formed, or may not be substantially formed, on the exposed surface of the conductive structure 240 due to selective deposition characteristics of the carbonyl compound.

Examples of the carbonyl compound having the functional group without an α-hydrogen may be the same as those described with respect to process P10 of FIG. 1. The inhibitor liner 250 may include the functional group included in the carbonyl compound or a derivative thereof.

Referring to FIG. 5C, in the resultant structure of FIG. 5B, the conductive structure 240 may be etched using the inhibitor liner 250 and the mask pattern 226 as an etch mask, and thus, a height of the conductive structure 240 may be reduced.

As an example, a dry etching process may be performed to etch the conductive structure 240. During the dry etching process, the inhibitor liner 250 covering the mask pattern 226 may improve an etching resistance of the mask pattern 226 in the dry etching process. For instance, during the etching of the conductive structure 240, the inhibitor liner 250 may inhibit the consumption of the mask pattern 226 and increase an etch selectivity of the conductive structure 240 over the mask pattern 226. During the etching of the conductive structure 240, at least portions of the inhibitor liner 250 and the mask pattern 226, which are in the resultant structure of FIG. 5B, may be consumed due to an etching atmosphere.

### EVALUATION EXAMPLE 1

In Evaluation example 1, it was confirmed via density functional theory (DFT) simulation using carbonyl compounds that an inhibitor liner could be selectively formed on a surface of a silicon nitride film by using a carbonyl compound having a functional group without an α-hydrogen.

More specifically, the DFT simulation was conducted on a surface of each of a silicon nitride film including Si₃N₄ and a silicon oxide film including SiO₂. The DFT simulation was conducted under the assumption that an amine group (—NH₂) was present on a surface of the silicon nitride film and a hydroxy group (—OH) was present on a surface of the silicon oxide film.

For all calculations used in the present evaluation examples, a density functional theory based on generalized gradient approximation (GGA)-Perdew-Burke-Enzerhopf (PBE) was used, and an interaction between a core electron and a valence electron was simulated using a projector augmented wave (PAW) method that was embedded in a Vienna Ab initio Simulation Package (VASP). In the VASP, a first principle calculation (Ab initio calculation) method, which is a calculation method using formulas, was used without consideration of empirical values through experiments.

In addition, a pseudopotential of the VASP used PAW-PBE, and specific data are as follows: Si (PAW_PBE Si 5 Jan. 2001), N (PAW_PBE N 8 Jan. 2002), H (PAW_PBE H 15 Jun. 2001), O (PAW_PBE O 8 Apr. 2002), C (PAW_PBE C 8 Apr. 2002), S (PAW_PBE S 6 Sep. 2000), F (PAW_PBE F 8 Apr. 2002). Furthermore, Si₃N₄-(001) and SiO₂-(111) surfaces, which were respectively obtained from β-Si₃N₄ and cristobalite-SiO₂ crystal structures, were used, and a slab model including five silicon (Si) atom layers and a vacuum of 15 Å was used for all surfaces. In a K-space, only gamma point calculations may be performed, and kinetic energy cut off of about 450 eV may be used. In addition, a D3 technique (e.g., Grimme's D3 empirical dispersion correction technique) was used to describe an interaction between a surface and molecules.

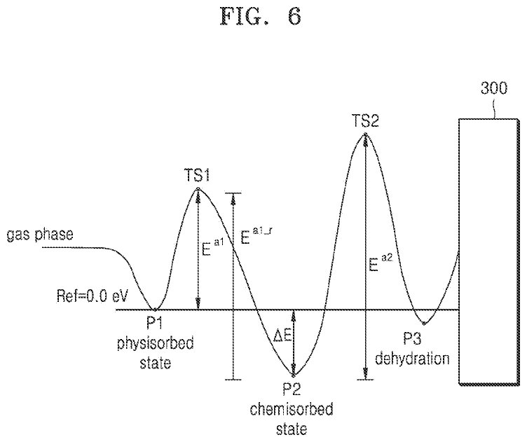

FIG. 6 is a potential energy diagram for explaining a reaction between an inhibitor material to be evaluated and a surface of a film 300 to be evaluated.

Between the inhibitor material to be evaluated and a surface of each of a Si₃N₄ film and a Sift film, a first energy barrier E^{a1} may be needed to cause a chemisorption reaction, and a second energy barrier E^{a2} may be needed to cause a dehydration reaction. To calculate the first energy barrier E^{a1} and the second energy barrier E^{a2}, a climbing-image nudge elastic band method (CI-NEB) method was used in super cell conditions so as to minimize an interaction between periodic images.

A chemical reaction of an inhibitor having an aldehyde group on a surface of each of a silicon nitride film and a silicon oxide film may proceed as shown in FIG. 6. In the potential energy diagram of FIG. 6, a reverse reaction activation energy E^{a1_r} may be determined by the following equation:

E^{a1_r}=E^{a1}−ΔE

Table 1 shows calculated energy parameters using various reaction conditions on the film 300 to be evaluated when the film 300 to be evaluated is the silicon nitride film. In Table 1, “SiN—NH₂” refers to a silicon nitride film having a surface at which an amine group is exposed as the film 300, “Path” refers to a reaction path, “Path 1” refers to a reaction path according to Reaction scheme 1A, and “Path 2” refers to a reaction path according to Reaction scheme 1B. As used herein, “CF3-benzal” refers to 4-(trifluoromethyl)benzaldehyde and “CH₃-S-benzal” refers to 4-(methylthio)benzaldehyde.

TABLE 1

| | Energy Parameters [Kcal/mol] | | | | |
|---|---|---|---|---|---|
| SiN—NH₂ | Path | E^{a1} | ΔE | E^{a1}_r | E^{a2} |
| Cyclohexanal | Path 1 | 28.8 | −4.5 | 33.3 | 49.7 |
| | Path 2 | | | | 52 |
| CF₃-benzal | Path 1 | 30.3 | −5.2 | 35.5 | 55.4 |
| CH₃—S-benzal | Path 1 | 37.7 | 1.4 | 36.3 | 53.8 |
| Decanal | Path 1 | 27.9 | −8.3 | 36.2 | 49.4 |
| | Path 2 | | | | 53.3 |

Table 2 shows the calculated energy parameters using various reaction conditions on the film 300 to be evaluated when the film 300 to be evaluated is the silicon oxide film. In Table 2, “SiO₂—OH” refers to a silicon oxide film having a surface on which a hydroxy group is exposed as the film 300, “Path” refers to a reaction path, “Path 1” refers to a reaction path according to Reaction scheme 2A, and “Path 2” refers to a reaction path according to Reaction scheme 2B.

TABLE 2

| | Energy Parameters [Kcal/mol] | | | | |
|---|---|---|---|---|---|
| SiO₂—OH | Path | E^{a1} | ΔE | E^{a1}_r | E^{a2} |
| Cyclohexanal | Path 1 | 44.7 | −2.3 | 47 | >150 |
| | Path 2 | | | | 67.4 |
| CF₃-benzal | Path 1 | 38.4 | −6.8 | 45.2 | >150 |
| CH₃—S-benzal | Path 1 | 34.5 | 0.3 | 34.2 | >150 |
| Decanal | Path 1 | 41.3 | 2.5 | 38.8 | >150 |
| | Path 2 | | | | 48.7 |

Referring to the results of Tables 1 and 2, second energy barriers E^{a2} of cyclohexanal and decanal on a surface of a silicon nitride film may not be much different from second energy barriers E^{a2} of cyclohexanal and decanal on a surface of a silicon oxide film. The above-described results may be obtained because it is possible for a reaction to proceed along a path according to Reaction scheme 2B when an α-hydrogen is present, as described in detail above. As can be seen from the results of Tables 1 and 2, because it is necessary to block a reaction path according to Reaction scheme 2B in order for an inhibitor material to have a selectivity with respect to the silicon nitride film, an aldehyde compound without an α-hydrogen may be used as the inhibitor material.

To facilitate a reaction that proceeds in a reaction path according to Reaction scheme 1A, it may be necessary to identify a head group to be substituted at a site of a functional group R of Reaction scheme 1A, from among aldehyde compounds without an α-hydrogen. To this end, DFT calculation results of 4-(trifluoromethyl)benzaldehyde having an electron-withdrawing group (—CF₃) and 4-(methylthio)benzaldehyde having an electron-donating group (—SCH₃) were compared.

Table 3 shows results of comparison of respective extracted evaluation results of a silicon nitride film and a silicon oxide film using 4-(trifluoromethyl)benzaldehyde from among the evaluation results obtained in Tables 1 and 2.

TABLE 3

| | Energy Parameters [Kcal/mol] | | | |
|---|---|---|---|---|
| —CF₃ | E^{a1} | ΔE | E^{a1}_r | E^{a2} |
| Silicon nitride | 30.3 | −5.2 | 35.5 | 55.4 |
| film | | | | |
| Silicon oxide film | 38.4 | −6.8 | 45.2 | >150 |

As can be seen from Table 3, a reaction of 4-(trifluoromethyl)benzaldehyde may be more dominant on the silicon nitride film than on the silicon oxide film in terms of the first energy barrier Eat, the reverse reaction activation energy E^{a1_r}, and the second energy barrier E^{a2}. For example, when an energy of about 100 kcal/mol is applied to 4-(trifluoromethyl)benzaldehyde, even a dehydration reaction may occur on the silicon nitride film, while a reverse reaction may occur on the silicon oxide film. As a result, 4-(trifluoromethyl)benzaldehyde may selectively cause a reaction according to Reaction scheme 1A only on the silicon nitride film.

However, it can be seen that when such an excessively high energy as to cause a dehydration reaction even on the silicon oxide film is applied to 4-(trifluoromethyl)benzaldehyde, 4-(trifluoromethyl)benzaldehyde may react on a surface of the silicon oxide film. Accordingly, when such an excessively high energy as to cause even the dehydration reaction on the silicon oxide film is not applied to 4-(trifluoromethyl)benzaldehyde, 4-(trifluoromethyl)benzaldehyde may selectively cause the reaction according to Reaction scheme 1A only on the silicon nitride film.

Table 4 shows results of comparison of respective extracted evaluation results of a silicon nitride film and a silicon oxide film using 4-(methylthio)benzaldehyde, from among the evaluation results obtained in Tables 1 and 2.

TABLE 4

| | Energy Parameters [Kcal/mol] | | | |
|---|---|---|---|---|
| —SCH₃ | E^{a1} | ΔE | E^{a1}_r | E^{a2} |
| Silicon nitride | 37.7 | 1.4 | 36.3 | 53.8 |
| film | | | | |
| Silicon oxide film | 34.5 | 0.3 | 34.2 | >150 |

As can be seen from Table 4 and FIG. 6, 4-(methylthio)benzaldehyde may be in an unstable chemisorbed state on the silicon nitride film, and the first energy barrier E^{a1} may be greater than the reverse reaction activation energy E^{a1_r}. Accordingly, a reverse reaction may be dominant. Therefore, it may be inferred that 4-(methylthio)benzaldehyde hardly reacts on the surface of the silicon nitride film.

Putting the results of Tables 3 and 4 together, it can be seen that, when the functional group of the aldehyde compound includes the electron-withdrawing group, electron density is reduced at the α-carbon site of the aldehyde compound so that reaction of the aldehyde compound may proceed relatively easily on the surface of the silicon nitride film.

In view of all the DFT simulation results according to Evaluation example 1,4-(trifluoromethyl)benzaldehyde, which includes the electron-withdrawing group and has no α-hydrogen, may be suitable as an inhibitor material that may selectively react on the surface of the silicon nitride film.

### EVALUATION EXAMPLE 2

Based on results obtained in Evaluation example 1, the reaction selectivity of each of 4-(trifluoromethyl)benzaldehyde and 4-(methylthio)benzaldehyde was evaluated experimentally using various methods.

To begin with, samples having structures in which a silicon nitride film and a silicon oxide film were exposed together on the same plane were prepared on a wafer. Thereafter, a first preprocessing process was performed on the samples as described below, and thus, organic impurities were removed from surfaces of the samples.

### 1. First Preprocessing Process (Organic Impurity Removing Process)

The first preprocessing process was performed by sequentially performing the following processes (1) to (3) on the samples in which the silicon nitride film and the silicon oxide film formed on the wafer were exposed together on the same plane:

(1) Ultrasonic cleaning process using dichloromethane for 10 minutes,

(2) Ultrasonic cleaning process with acetone for 10 minutes, and

(3) Ultrasonic cleaning process with methanol for 10 minutes.

### 2. Second Preprocessing Process (Native Oxide Film Removing Process)

The second preprocessing process was performed by sequentially performing the following processes (4) to (6) on the samples that had undergone the first preprocessing process:

(4) Process of dipping the samples in a 1% hydrogen fluoride (HF) aqueous solution for about 1 minute,

(5) Cleaning process using ultrapure water, and

(6) Drying process using argon (Ar) flow.

### EXAMPLES 1 TO 5

### Wet-Type Reaction

The samples that had undergone the second preprocessing process were dipped in a 4-(trifluoromethyl)benzaldehyde solution of various concentrations in an Ar atmosphere at various temperatures for various time periods, Thereafter, the samples were taken out of the 4-(trifluoromethyl)benzaldehyde solution, cleaned with methanol, and dried using Ar flow.

Thereafter, the obtained resultant structures were subjected to surface analysis using X-ray photoelectron spectroscopy (XPS). Thus, it was ascertained whether an inhibitor liner obtained from 4-(trifluoromethyl)benzaldehyde had been formed in the resultant structures. To ascertain whether the inhibitor liner was formed, the presence or absence of an adsorption peak due to a fluorine atom was confirmed on a surface of each of the resultant structures.

Table 5 shows results of ascertaining whether the inhibitor liner was formed on the silicon nitride film (SiN) and the silicon oxide film (SiO₂), which were included in each of the resultant structures, according to the type of solvent included in 4-(trifluoromethyl)benzaldehyde solution, the concentration of 4-(trifluoromethyl)benzaldehyde in the 4-(trifluoromethyl)benzaldehyde solution, and the dipping time.

TABLE 5

| | Dipping condition | | | | | |
|---|---|---|---|---|---|---|
| | | CF₃-benzal | Dipping | Dipping | Film | |
| | | Concen- | temperature | time | selectivity | |
| Example | Solvent | tration | [° C.] | [hr] | SiN | SiO₂ |
| 1 | MeOH | 0.4 M | 65 | 8 | ◯ | X |
| 2 | MeOH | 0.4 M | 65 | 16 | ◯ | X |
| 3 | THF | 0.4 M | R.T. | 5 | ◯ | X |
| 4 | Neat | 100% | R.T. | 5 | ◯ | X |
| 5 | Neat | 100% | 100 | 5 | ◯ | ◯ |

In Table 5, “MeOH” refers to methanol, “THF” refers to tetrahydrofuran, “Neat” refers to a case in which no solvent is used, and “R.T.” indicates room temperature. As used herein, the term “room temperature” refers to a temperature of about 20° C. to about 28° C. In the film selectivity of Table 5, “o” indicates that an inhibitor liner is formed on a surface of a film, and “X” indicates that the inhibitor liner is not formed on the surface of the film.

As can be seen from the results of Table 5, an inhibitor liner obtained from 4-(trifluoromethyl)benzaldehyde was not formed on a surface of the silicon oxide film but formed selectively only on a surface of the silicon nitride film. Moreover, the inhibitor liner was also formed on the surface of the silicon oxide film when a dipping reaction temperature was about 100° C. The above-described result may be consistent with the simulation results in Table 3, which show that when such an excessively high energy as to cause a dehydration reaction even on the silicon oxide film is applied to 4-(trifluoromethyl)benzaldehyde, 4-(trifluoromethyl)benzaldehyde may react on a surface of the silicon oxide film.

### EXAMPLES 6 TO 10

### Dry-Type Reaction

A vapor deposition process for forming an inhibitor liner was performed by using an ALD system on samples, which had undergone the second preprocessing process under the following various conditions.

### (Condition)

Reaction temperature: 100° C. to 300° C.

Reaction pressure: 4000 Pa

Reaction time: 30 seconds to 600 seconds

Heating temperature of source container: 70° C.

Inner pressure of source container: 100 Pa

Carrier gas: Ar

Carrier gas flow rate: 200 mL/sec

Thereafter, the obtained resultant structures were subjected to surface analysis using XPS. Thus, it was ascertained whether an inhibitor liner obtained from 4-(trifluoromethyl)benzaldehyde had been formed in the resultant structures. To ascertain whether the inhibitor liner was formed, the presence or absence of an adsorption peak due to a fluorine atom was confirmed on a surface of each of the resultant structures.

Table 6 shows results of ascertaining whether the inhibitor liner was formed on the silicon nitride (SiN) film and the silicon oxide (Sift) film, which were included in each of the resultant structures, according to the temperature at which a 4-(trifluoromethyl)benzaldehyde source was supplied, the process pressure, the substrate temperature, and the process time.

TABLE 6

| | Vapor deposition condition | | | | | |
|---|---|---|---|---|---|---|
| | Supply | Process | Substrate | Process | Film | |
| | temperature | pressure | temperature | time | selectivity | |
| Example | [° C.] | [torr] | [° C.] | [sec] | SiN | SiO₂ |
| 6 | 40 | 30 | 100 | 30 | ◯ | X |
| 7 | 70 | 30 | 100 | 600 | ◯ | X |
| 8 | 70 | 30 | 100 | 600 | ◯ | X |
| 9 | 70 | 30 | 200 | 600 | ◯ | X |
| 10 | 70 | 30 | 300 | 600 | ◯ | ◯ |

As can be seen from the results of Table 6, when a reaction temperature was about 100° C. or about 200° C., an inhibitor obtained from 4-(trifluoromethyl)benzaldehyde was not formed on a surface of the silicon oxide film but formed selectively only on a surface of the silicon nitride film. Moreover, when the reaction temperature was about 300° C., the inhibitor liner was also formed on the surface of the silicon oxide film. The above-described result may be substantially consistent with the simulation results shown in Table 3 and the result of Example 5. That is, it can be seen that, according to a method of manufacturing an IC device, the type of a target film on which the inhibitor liner is to be formed may be controlled by controlling a reaction temperature during the formation of the inhibitor liner.

### EXAMPLES 11 TO 14

For carbonyl compounds having a functional group without an α-hydrogen, when the functional group includes an electron-withdrawing group, the effect of the electron-withdrawing group on film selectivity was evaluated, and the evaluation results are shown in Table 7.

For the results in Table 7, an evaluation process using a wet-type reaction was performed in substantially the same manner as in the evaluation process of Examples 1 to 5. Here, compounds (inhibitors) to be evaluated included 4-(trifluoromethyl)benzaldehyde (4TFBA), 3,5-bis(trifluoromethyl)benzaldehyde (BTFBA), and 3-(trifluoromethyl)benzaldehyde (3TFBA) as aldehyde compounds and included 3,5-bis(trifluoromethyl)acetophenone (BTFAP) as a ketone compound.

TABLE 7

| | Dipping condition | | | | | |
|---|---|---|---|---|---|---|
| | | Inhibitor | Dipping | Dipping | Film | |
| | | Concen- | temperature | time | selectivity | |
| Example | Inhibitor | tration | [° C.] | [hr] | SiN | SiO₂ |
| 11 | 4TFBA | 100% | R.T. | 5 | ◯ | X |
| 12 | BTFBA | 100% | R.T. | 5 | ⊚ | X |
| 13 | 3TFBA | 100% | R.T. | 5 | ◯ | X |
| 14 | BTFAP | 100% | R.T. | 5 | ◯ | X |

In Table 7, “R.T.” denotes room temperature. In the film selectivity of Table 7, “o” and “⊚” indicate that an inhibitor liner is formed on a surface of a film, and “X” indicates that the inhibitor liner is not formed on the surface of the film. Specifically, “⊚” indicate that a size of an adsorption peak due to a fluorine atom is greater than that in the case of “o” in the results of surface analysis using XPS.

From the results of Table 7, it was confirmed that in all the compounds (inhibitors) to be evaluated, the inhibitor liner was selectively formed on the surface of the silicon nitride film over the silicon oxide film. In particular, it was confirmed that 3,5-bis(trifluoromethyl)benzaldehyde (BTFBA) having two electron-withdrawing groups (—CF₃) had higher reactivity than other compounds. Furthermore, similar to the aldehyde compound, in the case of 3,5-bis(trifluoromethyl)acetophenone, a ketone compound, it was confirmed that an inhibitor liner was formed only on the surface of the silicon nitride film and was not formed on the silicon oxide film.

### COMPARATIVE EXAMPLES 1 TO 5

An evaluation process using a wet-type reaction was performed in the same manner as in Examples 1 to 5 except that 4-(methylthio)benzaldehyde was used instead of 4-(trifluoromethyl)benzaldehyde. The evaluation results are shown in Table 8.

TABLE 8

| | Dipping condition | | | | | |
|---|---|---|---|---|---|---|
| Com- | | CF₃-benzal | Dipping | Dipping | Film | |
| parative | | Concen- | temperature | time | selectivity | |
| example | Solvent | tration | [° C.] | [hr] | SiN | SiO₂ |
| 1 | MeOH | 0.4 M | 65 | 8 | X | X |
| 2 | MeOH | 0.4 M | 65 | 16 | X | X |
| 3 | THF | 0.4 M | R.T. | 5 | X | X |
| 4 | Neat | 100% | R.T. | 5 | X | X |
| 5 | Neat | 100% | 100 | 5 | X | X |

As can be seen from the results of Table 8, when 4-(methylthio)benzaldehyde having an electron-donating group (—SCH₃) was used, an inhibitor liner was not formed on the surface of the silicon oxide film or the surface of the silicon nitride film. The above-described result may be consistent with the simulation results shown in Table 4.

Comparative examples 1 to 5 show the results of evaluation using a wet-type reaction. However, in view of the fact that the evaluation results of Examples 6 to 10 (dry-type reaction of 4-(trifluoromethyl)benzaldehyde) were substantially consistent with the evaluation results of Examples 1 to 5 (wet-type reaction of 4-(trifluoromethyl)benzaldehyde) in terms of film selectivity, it can be predicted that the evaluation results of a dry-type reaction of 4-(methylthio)benzaldehyde will be substantially consistent with the results of Table 8.

### EXAMPLES 15 TO 18

(Comparison of Deposited Thicknesses of Upper Films Inhibitor Liner According to the Presence or Absence of an Inhibitor liner)

Samples in which a silicon nitride film was formed on a wafer were prepared. Thereafter, the silicon nitride film included in each of the samples was dry preprocessed by sequentially performing the following processes (1) to (3) on each of the samples. Next, an inhibitor liner was formed by a dry reaction on the preprocessed silicon nitride film of each of the samples by sequentially performing the following processes (4) and (5). The process of forming the inhibitor liner was performed by applying the same process conditions as those described above in Examples 6 to 10 except for the conditions of the following processes (4) and (5).

(1) Process of thermally stabilizing the samples while maintaining a substrate temperature of about 240° C. to about 250° C. in an ALD system

(2) Process of processing the silicon nitride film included in each of the samples with H2 plasma at a plasma power of about 100 W for about 10 minutes in the ALD system

(3) Process of purging the ALD system for about 1 minute

(4) Vapor deposition process for forming the inhibitor liner on the silicon nitride film of each of the samples for about 10 minutes while maintaining a substrate temperature at a reaction temperature of about 240° C. by using 4-(trifluoromethyl)benzaldehyde

(5) Process of purging the ALD system for about 10 seconds

After the inhibitor liner was formed on the silicon nitride film of each of the samples as described above, a process of forming upper films including various components was performed on each of the samples by continuously performing the following processes (6) to (8) on the obtained resultant structure.

(6) Process of supplying a precursor A for forming an upper film to form a chemisorbed layer of the precursor A and purging the ALD system

(7) Process of supplying a reactive gas B onto the chemisorbed layer of the precursor A and purging the ALD system

(8) Process of repeating a cycle including the processes (6) and (7) a desired number of times

The precursor A and the reactive gas B used in Examples 15 to 18 are as follows.

Example 15: To Form an Upper Film Including a Hafnium Oxide Film, tetrakis(ethylmethylamino)hafnium(IV) (TEMAH) was used as the precursor A, and H₂O was used as the reactive gas B.

Example 16: To form an upper film including a hafnium nitride film, TEMAH was used as the precursor A, and NH₃ was used as the reactive gas B.

Example 17: To form an upper film including an aluminum oxide film, tetraethylaluminum (TEA) was used as the precursor A, and H₂O was used as the reactive gas B.

Example 18: To form an upper film including a niobium oxide film, tert-butylimido tris(methylethylamino)niobium (PBTEMN) was used as the precursor A, and O₂ was used as the reactive gas B.

### EVALUATION EXAMPLE 3

To evaluate thickness selectivities of the various upper films obtained in Examples 15 to 18, Comparative examples were prepared in which various upper films were formed in the same manner as in Examples 15 to 18 on a silicon nitride film on which a preprocessing process of the processes (1) to (3) according to Examples 15 to 18 was performed but the processes (4) and (5) for forming the inhibitor liner were omitted.

Subsequently, a thickness of the upper film formed on the silicon nitride film in Examples 15 to 18 in which the inhibitor liner was formed according to the processes (4) and (5) was compared with a thickness of the upper film formed on the silicon nitride film in Comparative examples in which the processes (4) and (5) for forming the inhibitor liner were omitted and the upper films were formed. For the comparison of the thicknesses, a metal XPS peak value obtained from each of the upper film formed on the silicon nitride film of each of Examples 15 to 18 and the upper film formed on the silicon nitride film of each of Comparative examples was converted into an area ratio. When a metal XPS area ratio of each of Comparative examples was set to 1, relative metal XPS area ratios of Examples 15 to 18 were calculated, reciprocals of the calculated metal XPS area ratios were evaluated as thickness selectivities, and the results are as shown in Table 9.

TABLE 9

| | Example 15 | Example 15 | Example 16 | Example 17 | Example 18 |
|---|---|---|---|---|---|
| | (14 cycles) | (28 cycles) | (14 cycles) | (14 cycles) | (25 cycles) |
| XPS area ratio | 0.54 | 0.62 | 0.69 | 0.78 | 0.7 |
| Thickness | 1.9 | 1.6 | 1.4 | 1.3 | 1.4 |
| selectivity | | | | | |

In Table 9, the number of cycles refers to the number of the processes (6) and (7) repeated in the process (8) to form the inhibitor liner on the silicon nitride film. As can be seen from the results of Table 9, when the inhibitor liner was formed on the silicon nitride film, compared to the case in which the inhibitor liner was not formed, it can be seen that a thickness of the upper film formed on the silicon nitride film was reduced to about 80% or less, and a deposition inhibition rate of the upper film formed on the silicon nitride film was increased by about 1.3 times or more.

While the inventive concept has been particularly shown and described with reference to embodiments thereof, it will be understood that various changes in form and details may be made therein without departing from the spirit and scope of the following claims.

What is claimed is:

1. A method of manufacturing an integrated circuit device, the method comprising:
forming a structure comprising a first material film and a second material film on a substrate, wherein the first material film comprises silicon atoms and nitrogen atoms and the second material film is devoid of nitrogen atoms, and wherein the first material film comprises a first exposed surface, and the second material film comprises a second exposed surface; and
applying to the structure a carbonyl compound having a functional group without an α-hydrogen to selectively form an inhibitor liner on the first exposed surface of the first material film and not form the inhibitor liner on the second exposed surface of the second material film.

2. The method of claim 1, wherein the carbonyl compound comprises an aldehyde compound represented by General Formula 1:
R¹—C(═O)—H [General Formula 1]
wherein, in General Formula 1, R¹ is a substituted or unsubstituted hydrocarbon group without an α-hydrogen, and is a substituted or unsubstituted C1 to C30 branched alkyl group, a substituted or unsubstituted C3 to C30 branched alkenyl group, a substituted or unsubstituted C2 to C30 alkynyl group, a substituted or unsubstituted C1 to C30 branched alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

3. The method of claim 1, wherein the carbonyl compound comprises an aldehyde compound represented by General Formula 1A, General Formula 1B, or General Formula 1C: 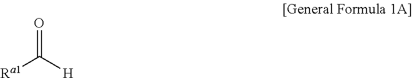
wherein, in General Formula 1A, R^{a1} is a substituted or unsubstituted C6 to C20 aryl group, a substituted or unsubstituted C2 to C20 heteroaryl group, a substituted or unsubstituted C7 to C20 alkylaryl group, or a combination thereof, 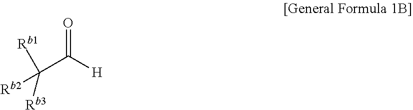
wherein, in General Formula 1B, each of R^{b1}, R^{b2}, and R^{b3} is independently a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof, 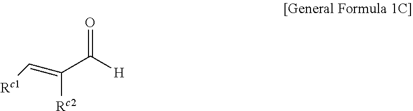
wherein, in General Formula 1C, each of R^{c1} and R^{c2} is independently a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

4. The method of claim 1, wherein the carbonyl compound comprises an aldehyde compound represented by General Formula 1D: 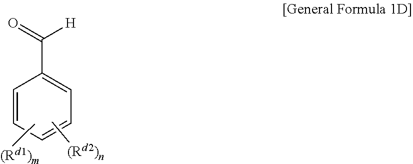
wherein, in General Formula 1D, R^{d1} is a methyl group or a trifluoromethyl group, R^{d2} is a C1 to C4 alkyl group, a C1 to C4 alkoxy group, a halogen, a hydroxy group, a nitro group, an amino group, a C1 to C4 monoalkylamino group, a C1 to C4 dialkylamino group, or a combination thereof, and each of m and n is an integer of 0 to 3, and 0≤(m+n)≤5.

5. The method of claim 1, wherein the carbonyl compound comprises a ketone compound represented by General Formula 2:
R²¹—C(═O)—R²² [General Formula 2]
wherein, in General Formula 2, R²¹ is a substituted or unsubstituted hydrocarbon group without an α-hydrogen, and is a substituted or unsubstituted C1 to C30 branched alkyl group, a substituted or unsubstituted C3 to C30 branched alkenyl group, a substituted or unsubstituted C2 to C30 alkynyl group, a substituted or unsubstituted C1 to C30 branched alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof, and R²² is a substituted or unsubstituted C1 to C6 alkyl group, a substituted or unsubstituted C2 to C6 alkenyl group, a substituted or unsubstituted C2 to C6 alkynyl group, or a combination thereof.

6. The method of claim 1, wherein the carbonyl compound comprises a ketone compound represented by General Formula 2A: 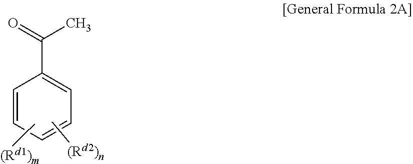
wherein, in General Formula 2A, R^{d1} is a methyl group or a trifluoromethyl group, R^{d2} is a C1 to C4 alkyl group, a C1 to C4 alkoxy group, a halogen, a hydroxy group, a nitro group, an amino group, a C1 to C4 monoalkylamino group, a C1 to C4 dialkylamino group, or a combination thereof, and each of m and n is an integer of 0 to 3, and 0≤(m+n)≤5.

7. The method of claim 1, wherein the carbonyl compound comprises 4-(trifluoromethyl)benzaldehyde, 3-(trifluoromethyl)benzaldehyde, 3,5-bis(trifluoromethyl)benzaldehyde, 3,5-bis(trifluoromethyl)acetophenone (3,5-bis(trifluoromethyl)acetophenone), phenylpropargyl aldehyde, 2-octynal, or a combination thereof.

8. The method of claim 1, wherein after forming the structure and before applying the carbonyl compound to the structure, the method further comprises preprocessing the structure to expose an amine group (—NH₂) on the first exposed surface of the first material film and expose a hydroxy group (—OH) on the second exposed surface of the second material film.

9. The method of claim 8, wherein the hydroxy group on the second exposed surface does not react with the carbonyl compound.

10. The method of claim 1, wherein the first material film comprises silicon nitride (SiN), silicon oxynitride (SiON), silicon oxycarbonitride (SiCON), silicon boron nitride (SiBN), silicon carbonitride (SiCN), or a combination thereof, and
the second material film comprises silicon oxide or a metal.

11. The method of claim 1, wherein the carbonyl compound is applied to the structure in a wet manner.

12. The method of claim 1, wherein the carbonyl compound is applied to the structure in a dry manner.

13. The method of claim 1, wherein the method further comprises etching the second material film after selectively forming the inhibitor liner.

14. A method of manufacturing an integrated circuit device, the method comprising:
forming a structure on a substrate, the structure including a first material film comprising silicon atoms and nitrogen atoms and a second material film that is devoid of nitrogen atoms;
preprocessing the structure to expose a first surface having an amine group (—NH₂) on the first material film and expose a second surface having a hydroxy group (—OH) on the second material film; and
applying a carbonyl compound having a functional group without an α-hydrogen to the structure to selectively form an inhibitor liner on the first surface and not form the inhibitor liner on the second surface.

15. The method of claim 14, after forming of the inhibitor liner, further comprising forming an upper film comprising a first portion and a second portion, the first portion covering the first material film, and the second portion covering the second material film, wherein a thickness of the first portion of the upper film is less than a thickness of the second portion thereof.

16. The method of claim 14, wherein the carbonyl compound comprises an aldehyde compound represented by General Formula 1 or a ketone compound represented by General Formula 2:
R¹—C(═O)—H [General Formula 1]
wherein, in General Formula 1, R¹ is a substituted or unsubstituted hydrocarbon group without an α-hydrogen, and is a substituted or unsubstituted C1 to C30 branched alkyl group, a substituted or unsubstituted C3 to C30 branched alkenyl group, a substituted or unsubstituted C2 to C30 alkynyl group, a substituted or unsubstituted C1 to C30 branched alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof,
R²¹—C(═O)—R²² [General Formula 2]
wherein, in General Formula 2, R²¹ is a substituted or unsubstituted hydrocarbon group without an α-hydrogen, and is a substituted or unsubstituted C1 to C30 branched alkyl group, a substituted or unsubstituted C3 to C30 branched alkenyl group, a substituted or unsubstituted C2 to C30 alkynyl group, a substituted or unsubstituted C1 to C30 branched alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof, and R²² is a substituted or unsubstituted C1 to C6 alkyl group, a substituted or unsubstituted C2 to C6 alkenyl group, a substituted or unsubstituted C2 to C6 alkynyl group, or a combination thereof.

17. The method of claim 14, wherein the functional group without an α-hydrogen comprises at least one electron-withdrawing group, and
the at least one electron-withdrawing group comprises a C1 to C10 alkyl group substituted with one or more fluorine atom(s), a C1 to C10 alkoxy group substituted with one or more fluorine atom(s), a C1 to C10 cycloalkyl group substituted with one or more fluorine atom(s), a cyano group (—CN), a nitrile group, a nitro group (—NO₂), a carboxyl group, or a combination thereof.

18. The method of claim 14, wherein the carbonyl compound comprises a compound having a structure selected from the following formulas: 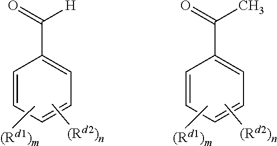
wherein, in the above formulas, R^{d1} is a methyl group or a trifluoromethyl group, R^{d2} is a C1 to C4 alkyl group, a C1 to C4 alkoxy group, a halogen, a hydroxy group, a nitro group, an amino group, a C1 to C4 monoalkylamino group, a C1 to C4 dialkylamino group, or a combination thereof, and each of m and n is an integer of 0 to 3, and 0≤(m+n)≤5.

19. A method of manufacturing an integrated circuit device, the method comprising:
forming a structure on a substrate, wherein the structure comprises an exposed nitride film comprising silicon atoms and nitrogen atoms and an exposed oxide film that is devoid of nitrogen atoms; and
applying to the exposed nitride film and the exposed oxide film a carbonyl compound having a functional group without an α-hydrogen to selectively form an inhibitor liner on the nitride film and not form the inhibitor liner on the oxide film,
wherein the carbonyl compound comprises an aldehyde compound represented by General Formula 1A, General Formula 1B, or General Formula 1C: 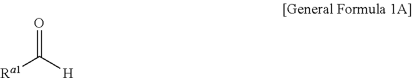
wherein, in General Formula 1A, R^{a1} is a substituted or unsubstituted C6 to C20 aryl group, a substituted or unsubstituted C2 to C20 heteroaryl group, a substituted or unsubstituted C7 to C20 alkylaryl group, or a combination thereof, 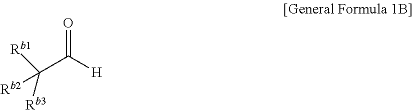
wherein, in General Formula 1B, each of R^{b1}, R^{b2}, and R^{b3} is independently a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof, and 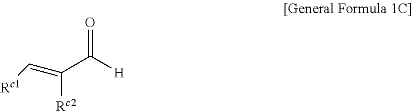
wherein, in General Formula 1C, each of R^{c1} and R^{c2} is independently a substituted or unsubstituted C1 to C20 alkyl group, a substituted or unsubstituted C3 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C6 to C30 arylalkyl group, a substituted or unsubstituted C8 to C30 arylalkenyl group, a substituted or unsubstituted C8 to C30 arylalkynyl group, a substituted or unsubstituted C2 to C30 heteroaryl group, a substituted or unsubstituted C7 to C30 alkylaryl group, or a combination thereof.

20. The method of claim 19, wherein the carbonyl compound comprises 4-(trifluoromethyl)benzaldehyde, 3-(trifluoromethyl)benzaldehyde, 3,5-bis(trifluoromethyl)benzaldehyde, phenylpropargyl aldehyde, 2-octynal, or a combination thereof.
